(19) United States
(12) Patent Application Publication
(10) Pub. No.: US 2010/0140790 A1
(43) Pub. Date: Jun. 10, 2010

(54) CHIP HAVING THERMAL VIAS AND SPREADERS OF CVD DIAMOND

(75) Inventors: Dadi Setiadi, Edina, MN (US); Hongyue Liu, Maple Grove, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/500,268

(22) Filed: Jul. 9, 2009

Related U.S. Application Data
(60) Provisional application No. 61/120,176, filed on Dec. 5, 2008.

(51) Int. Cl. H01L 23/373; H01L 23/48; H01L 23/52

(52) U.S. Cl. 257/698; 257/720; 257/724; 257/E23.111; 257/E23.011; 257/E23.141

(57) ABSTRACT

An integrated circuit chip having a heat spreader comprising CVD diamond extending along the chip support body and thermal vias extending through the support body in regions free of active devices or functional elements. The thermal vias may thermally conductive and electrically conductive or may be thermally conductive and electrically resistive. The integrated circuit chips may be 3D integrated circuit chips.

### RELATED APPLICATION

This application claims priority to U.S. provisional patent application No. 61/120,176, filed on Dec. 5, 2008 and titled “3D IC Thermal Via Using CVD Diamond”. The entire disclosure of application No. 61/120,176 is incorporated herein by reference.

### BACKGROUND

As technology progresses with the desire to obtain more capacity, integrated circuit (IC) chip areas and wire lengths continue to increase, which unfortunately causes such problems as increased interconnect delays, power consumption, and temperature, all of which can have serious implications on reliability, performance, and design effort. Three dimensional (3D) IC technology attempts to overcome some of these limitations by stacking multiple active layers into a monolithic structure, using special processing technologies such as silicon-on-insulator (SOI) or wafer bonding. By expanding vertically rather than spreading out over a larger area, the chip space is better utilized, interconnects are decreased, and transistor packing densities are increased, leading to better performance and power efficiency. Despite the advantages that 3D ICs have over two dimensional ICs, thermal effects are more pronounced in 3D ICs because of higher power densities and greater thermal resistance along heat dissipation paths.

It is desirable to mitigate the thermal problem associated with 3D ICs.

### BRIEF SUMMARY

The present disclosure relates to integrated circuit chips having heat conduction paths in the chip to minimize and preferably eliminate localized hot spots. The chips include a thermal spreader and thermal vias to dissipate heat. At least the thermal spreader is chemical-vapor-deposition (CVD) diamond.

In one particular embodiment, this disclosure provides an integrated circuit chip having a support body having thereon at least one active device, a heat spreader comprising CVD diamond extending along the support body, and at least one thermal via extending through the support body.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1 is a schematic perspective view of an integrated circuit with a uniform placement of thermal vias;

FIG. 2 is a schematic cross-sectional side view of a three-dimensional integrated circuit having electrical vias and thermal spreaders;

FIG. 3 is a schematic cross-sectional side view of a three-dimensional integrated circuit having electrical vias and thermal vias;

FIG. 4 is a schematic cross-sectional side view of an integrated circuit having thermal vias and a thermal spreader;

FIG. 5 is a schematic cross-sectional side view of another integrated circuit having thermal vias and a thermal spreader;

FIG. 6 is a schematic cross-sectional side view of a packaged integrated circuit having thermal vias and a thermal spreader; and

FIG. 7 is a schematic cross-sectional side view of a packaged integrated circuit of FIG. 6 incorporated into a two layer printed circuit board structure.

The figures are not necessarily to scale. Like numbers used in the figures refer to like components. However, it will be understood that the use of a number to refer to a component in a given FIG. is not intended to limit the component in another FIG. labeled with the same number.

### DETAILED DESCRIPTION

As integrated circuits (ICs) are being built vertically (i.e., three-dimensionally, 3D) to save space, thermal problems are becoming more evident and more problematic. Incorporating thermal vias into 3D integrated circuits is a manner of mitigating thermal issues by lowering the thermal resistance of the IC chip itself. By utilizing thermal vias and/or thermal spreaders, localized hot spots are inhibited and typically eliminated due to direct heat conduction paths through the thermal vias and/or spreaders. The thermal vias and spreaders are formed from chemical-vapor-deposition (CVD) diamond.

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense. Any definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

It is noted that terms such as “top”, “bottom”, “above, “below”, etc. may be used in this disclosure. These terms should not be construed as limiting the position or orientation of a structure, but should be used as providing spatial relationship between the structures.

The present disclosure relates to integrated circuit structures that have thermal vias and/or thermal spreader(s) formed of CVD diamond. CVD diamond is the desired material because it has high thermal conductivity and high electrical resistivity, it has a coefficient of thermal expansion close to that of silicon, and its processing is compatible with semiconductor processes. Incorporation of thermal vias and/or thermal spreaders into two-dimensional and three-dimensional integrated circuits and packages is a means for mitigating thermal issues by lowering the thermal resistance of the chip itself. Additionally, localized hot spots are eliminated due to a direct heat conduction path formed by the thermal vias and the thermal spreaders. While the present disclosure is not so limited, an appreciation of various aspects of the disclosure will be gained through a discussion of the examples provided below.

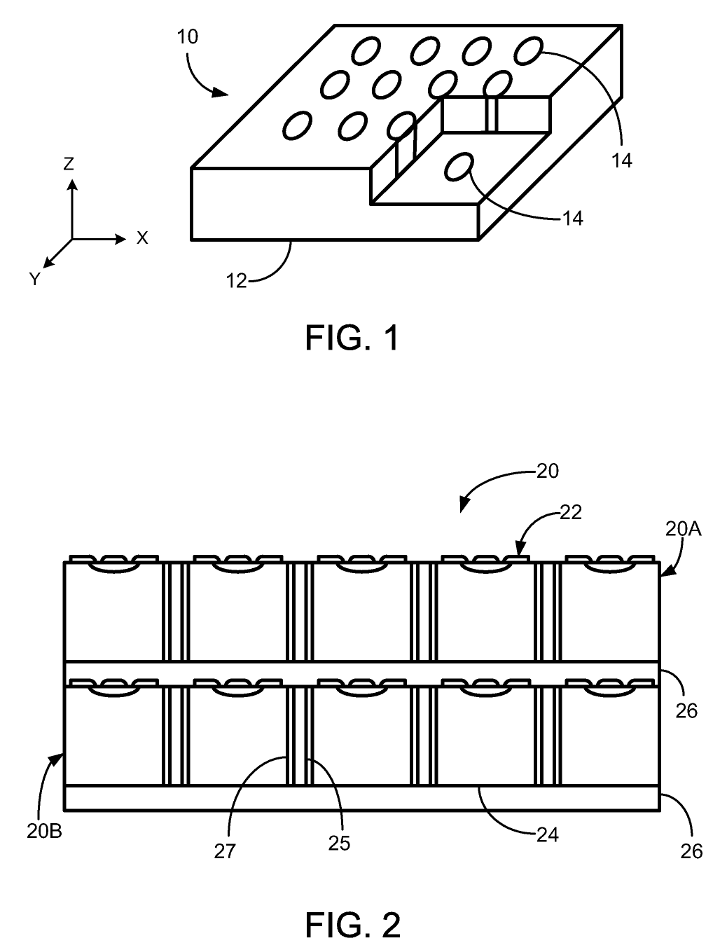

The chip or integrated circuits can be designed with specific areas reserved for the thermal vias and/or thermal spreaders. In the embodiment shown in FIG. 1, a uniform density of thermal vias is shown throughout a chip 10. Chip 10 has a body 12, with thermal vias 14 composed of CVD diamond distributed along the width (X-direction) and depth (Y-direction) of chip 10. Thermal vias 14 are electrically isolated (insulated) from each other, and are oriented vertically (Z-direction) within body 12. In this embodiment, vias 14 extend the thickness (Z-direction) through body 12; in alternate embodiments, one or all vias 14 may not extend the entire thickness of body 12. Vias 14 are illustrated as generally circular, but may be any shape, including circular, oval, ellipsoid, rectangular and square. Although not illustrated in FIG. 1, chip 10 includes active devices such as complementary metal oxide semiconductor (CMOS) transistors or bipolar transistors or other memory elements in body 12 between vias 14. Active devices may alternately be referred to as functional devices or elements.

The placement and density of vias 14 in body 12 can be determined by a placement algorithm or other method. The density of thermal vias 14 in body 12 determines the thermal conductivity of the region which in turn determines the thermal properties of the entire chip 10. Generally in all embodiments of chip 10, there are various obstacles (e.g., functional elements such as memory elements) to placement of thermal vias 14. Placing these obstacles in specific regions allows for easy routing of vias 14 around the predictable obstacles. In some embodiments, the placement and/or density of these obstacles is limited to a particular area so that the design does not become unroutable. It also allows for regularity and uniformity in the entire design process.

FIG. 2 illustrates a three-dimensional (3D) chip 20 having CVD diamond thermal spreaders. Chip 20 has two tiers 20A, 20B of functional structure, which includes in this embodiment, active devices 22 orderly positioned on a supporting body 24 such as silicon.

Chip 20 includes thermal or heat spreaders 26 between tiers 20A, 20B. Thermal spreaders 26 are thermally conductive, but electrically isolative. In the illustrated embodiment, thermal spreaders 26 are a continuous layer of CVD diamond extending the width and depth of chip 20 to its outer edges. Thermal spreader 26 may be, for example, 100 nm-10 μm thick. Thermal spreaders 26 provide a direct path for heat from within chip 20 to dissipate through and out from chip 20. In some embodiments, thermal spreaders 26 may not be a continuous layer of CVD diamond, but may be a uniform or random lattice of CVD diamond that extends across the width and depth of chip 20 to its outer edges.

In order for active devices 22 to operate, chip 20 includes a plurality of electrically conducting vias 25 extending vertically and providing electrical flow between top tier 20A and lower tier 20B. Additionally, electrical vias 25 connect thermal spreaders 26. Examples of suitable materials for electrical vias 25 are copper, tungsten, mixtures thereof and alloys thereof, which are encircled or surrounded by an insulating or dielectric layer 27, for example, silicon dioxide, to ensure electrical insulation between adjacent electrical vias 25. Electrical vias 25 may be, for example, about 50 μm long. In some embodiments, electrical vias 25 also function as heat or thermal vias, dissipating heat from tier 20A and tier 20B to thermal spreaders 26.

CVD diamond, classified as a dielectric, has an electrical resistivity comparable with the electrical resistivity of silicon dioxide. Because of this, thermal spreaders 26 will provide thermal interconnect with electrical vias 25 but will electrically isolate vias 25 from each other.

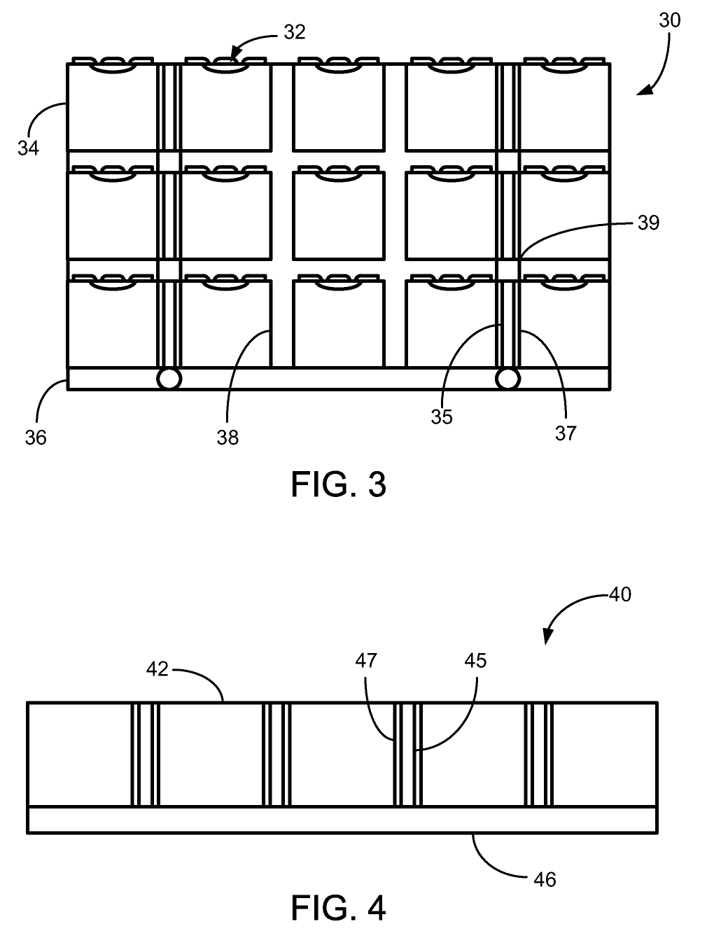

The CVD diamond may be used for thermal vias as well as for thermal spreaders. FIG. 3 illustrates a three-dimensional (3D) chip 30 having CVD diamond thermal spreaders and CVD diamond thermal vias. The thermal vias connect to each other through the thermal spreader that is thermally conductive, but electrically isolative. Chip 30 is similar to chip 20, except that chip 30 has three tiers of functional structure and also includes CVD diamond thermal vias. Referring to FIG. 3, chip 30 has active devices 32 (e.g., CMOS and/or bipolar transistors) orderly positioned on a supporting body 34 such as silicon.

Chip 30 includes thermal or heat spreaders 36, formed by a continuous layer of CVD diamond, extending to the outer edges of chip 30 between adjacent tiers. Thermal spreader 36 may be, for example, 100 nm-10 μm thick. In some embodiments, thermal spreaders 36 may not be a continuous layer of CVD diamond, but may be a uniform or random lattice of CVD diamond that extends across the width and depth of chip 30 to its outer edges.

Chip 30 also includes CVD diamond thermal vias 38, extending vertically between adjacent tiers and providing thermal or heat flow between the tiers. Additionally, thermal vias 38 connect with thermal spreaders 36, forming a 3D lattice of CVD diamond throughout chip 30. In some embodiments, thermal vias 38 are perpendicular or orthogonal to heat spreaders 36, and multiple thermal vias 38 are parallel to each other. Heat from chip 30 is dissipated through vias 38 and spreaders 36, to the outer edges of chip 30. Thermal vias 38 may have, for example, a diameter or largest dimension of about 1000 nm (1 μm)-10 μm, in some embodiments about 5 μm, and may extend about 50 μm long between thermal spreaders 36. Thermal vias 38 may be a continuous line or column of CVD diamond that extends from the top surface to the bottom of chip 30, or in some embodiments, thermal vias 38 extend through a tier, and vertically adjacent thermal vias are connected to each other by a thermal contact joint. In most embodiment, thermal vias in adjacent tiers are vertically aligned,

In order for active devices 32 to operate, chip 30 includes a plurality of electrically conducting vias 35 extending vertically and providing electrical flow between tiers.

Examples of suitable material for electrical vias 35 include copper, tungsten, mixtures thereof and alloys thereof, which are encircled or surrounded by an insulating or dielectric layer 37, for example, silicon dioxide, to ensure electrical insulation between adjacent electrical vias 35. Electrical vias 35 from separate tiers are connected to each other through an electrical contact 39. Examples of suitable materials for electrical contact 39 include copper, copper tin alloy, and gold tin alloy, which provide an electrical conduction. Electrical contact 39 is surrounded by thermal spreader 36; that is, in locations where electrical contact 39 is present, thermal spreader 36 has a void or aperture for retention of contact 39 therein.

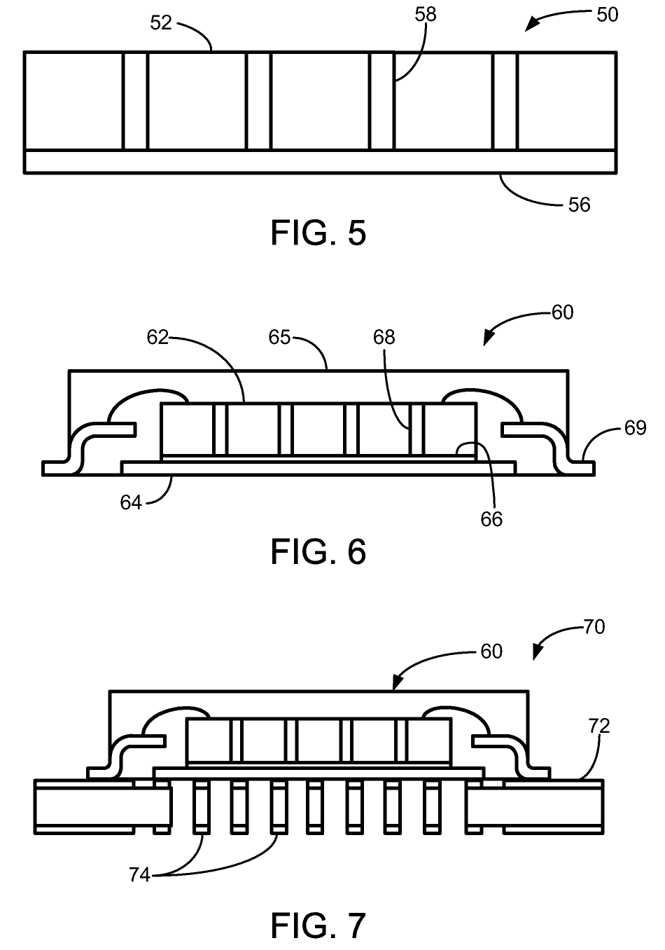

CVD diamond thermal vias and/or thermal spreaders may be used for a single level chip, such as for a high power device that creates a lot of heat, such as a power device, a microprocessor, etc. FIG. 4 illustrates a single chip with a CVD diamond thermal spreader and with vias that function both as electrical vias and thermal vias. In a single level chip, the vias are not needed for electrical interconnect between multiple tiers, but are used predominantly for thermal conduction. FIG. 5 illustrates a single chip with a CVD diamond thermal spreader and with CVD diamond thermal vias, with no electrical via. The various features and elements of these single chips are the same as those of chips 10, 20, 30, described above, unless indicated otherwise.

Chip 40 of FIG. 4 has a support body 42 that includes thermal or heat spreader 46, formed by a layer of CVD diamond, extending to the outer edges of chip 40. Chip 40 also includes a plurality of electrically conducting vias 45, for example, copper/tungsten, which is encircled or surrounded by an insulating or dielectric layer 47, for example, silicon dioxide, to ensure electrical insulation between adjacent electrical vias 45. Electrical vias 45 also provide a vertical path to spreader 46 and the outer edges of chip 40 for thermal dissipation from chip 40.

Chip 50 of FIG. 5 has a support body 52 that includes thermal or heat spreader 56, formed by a layer of CVD diamond, extending to the outer edges of chip 50. Chip 50 also includes CVD diamond thermal vias 58. Heat from chip 50 is dissipated through vias 58 and spreader 56 to the outer edges of chip 50 and to the bottom of chip 50.

As indicated above, the thermal spreaders and thermal vias are composed of CVD diamond. CVD diamond has high thermal conductivity (k) (about 1200 W/m K) and high electrical resistivity (about 10¹³-10¹⁶ ohms-cm), has a coefficient thermal expansion close to that of silicon, and its processing is compatible with semiconductor processes. With its electric resistivity comparable to that of silicon dioxide, CVD diamond is classified as a dielectric layer.

The value of the thermal conductivity, k, in any particular direction of the chip (width or X-direction, depth or Y-direction, thickness or Z-direction) corresponds to the density of thermal vias and/or spreaders that are arranged in that direction. Increasing the number of thermal vias in one direction (e.g., the X-direction) does increase the thermal conductivity in the other directions (e.g., the Y-direction) but at an order of magnitude less. However, for simplicity herein, the interdependence can be considered to be negligible, and the k's in the X-, Y- and Z-directions can be considered to be independent to a certain extent.

Current integration technologies for producing 3D integrated circuits (such as chips 10, 20, 30) results in the tiers or layers (e.g., tiers 20A, 20B of FIG. 2) being closely stacked together and the design space being tightly compressed in the thickness or Z-direction. In addition, the location of any heat sinks in relation to heat sources produces a heat flux that is primarily downward in direction with very minor lateral components. Furthermore, with the thermal via regions in the chip designed to be oriented vertically in the support body (e.g., support body 12, 24, 34, etc.), lateral thermal vias are more difficult to position and would have little effect. As a result, lateral thermal conductivities (in the X- and Y-directions) are generally unchanged because the thermal gradients in the vertical Z-direction are almost two orders of magnitude larger than in the lateral directions. For these reasons, in addition to the presence of thermal vias, laterally extending thermal spreaders between tiers are preferably included. For adequate spreading and dissipation, both the thermal via and the thermal spreader should be capable of rapidly moving high heat loads from high heat flux hot spots, particularly by the thermal spreader in the in-plane direction (X-Y orientation).

CVD diamond, the material for the thermal spreaders and thermal vias of this disclosure, has a very high in-plane thermal conductivity. In addition, CVD diamond is compatible with other semiconductor process, and has coefficient of thermal expansion (CTE) properties that can be tailored to provide excellent CTE compatibility with semiconductor materials. CVD diamond also has high structural strength, stiffness and low density. Table 1 shows properties of the CVD diamond.

TABLE 1
Properties of CVD Diamond

| Parameter | Value | Unit |
|---|---|---|
| Chemical composition | 100 | % |
| Polycrystalline diamond (carbon) | | |
| Density | 3.5 | Q/cm³ |
| Electrical resistivity | 10¹³-10¹⁶ | Ohm-cm |
| Thermal conductivity | 1200 | W/m K |
| Coefficient thermal expansion (CTE) | 1.5-1.8 | ppm/K |
| Hardness | 10⁴ | Kg/mm² |

CVD diamond, either as a thermal spreader or thermal via, is formed using chemical vapor deposition. CVD diamond formation involves feeding various gases (at least one of which includes a carbon source) into a chamber, energizing the gas and providing conditions for diamond growth on the desired target substrate. Suitable energy sources include hot filament, microwave power, and arc discharges, which are intended to generate a plasma in which the gases break down and more complex chemistries occur. A thermal spreader may be remotely formed and then subsequently incorporated with the support body, or, the thermal spreader may be formed directly on the support body. Thermal vias may be formed (e.g., deposited) directly into channels in the support body.

FIGS. 1-5 have provided various single layer and 3D chips having CVD diamond thermal spreaders with or without CVD diamond thermal vias. Any of the structures can be incorporated into quad flat no-lead (QFN) packages, an example of which is shown in FIG. 6. Packaged chip 60 has an integrated circuit chip (IC) 62 seated on a package base 64 and encased in an electrically insulating package 65, such as plastic. Chip 62 includes a CVD diamond thermal spreader 66 and CVD diamond thermal vias 68. Connected to chip 62 are electrical leads 69. Packaged chip 60 is incorporated into the two layer printed circuit board (PCB) structure 70 in FIG. 7. Structure 70 has chip 60 mounted on PCB structure 72, which has a built-in heat sink or cooling structure 74, in the illustrated embodiment, a plurality of fins. In structure 70, heat from chip 60 is primarily dissipated through the back of package 65 and through PCB structure 72 and cooling structure 74.

Thus, embodiments of the CHIP HAVING THERMAL VIAS AND SPREADERS OF CVD DIAMOND are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present invention is limited only by the claims that follow.

What is claimed is:

1. An integrated circuit chip comprising:
a support body having thereon at least one active device;
a heat spreader comprising CVD diamond extending along the support body; and
at least one thermal via extending through the support body.

2. The integrated circuit chip of claim 1 wherein the at least one thermal via comprises CVD diamond.

3. The integrated circuit chip of claim 1 wherein the at least one thermal via comprises copper and/or tungsten.

4. The integrated circuit chip of claim 1 comprising a plurality of thermal vias extending through the support body.

5. The integrated circuit chip of claim 4 wherein the plurality of thermal vias comprise CVD diamond.

6. The integrated circuit chip of claim 1 wherein the heat spreader is 100 nm-10 μm thick.

7. The integrated circuit chip of claim 1 wherein the chip is a three-dimensional (3D) chip comprising:
a first tier comprising a first support body having thereon at least one active device, a first heat spreader comprising CVD diamond extending along the first support body, and at least one first thermal via extending through the first support body; and
a second tier comprising a second support body having thereon at least one active device, a second heat spreader comprising CVD diamond extending along the second support body, and at least one second thermal via extending through the second support body, the first heat spreader positioned between the first support body and the second support body.

8. The 3D integrated circuit chip of claim 7 wherein the at least one first thermal via comprises CVD diamond and the at least one second thermal via comprises CVD diamond.

9. The 3D integrated circuit chip of claim 7 comprising a plurality of first thermal vias extending through the first support body and a plurality of second thermal vias extending through the second support body.

10. The 3D integrated circuit chip of claim 9 wherein the plurality of first thermal vias comprise CVD diamond and the plurality of second thermal vias comprise CVD diamond.

11. The integrated circuit chip of claim 1 wherein the at least one active device is a CMOS transistor or a bipolar transistor.

12. An integrated circuit chip comprising:
a support body having side edges and a thickness;
a plurality of functional elements arranged on the support body to form regions free of functional elements;
at least one thermal via extending through the thickness of the support body in the regions free of functional elements; and
a heat spreader comprising CVD diamond extending to the side edges along the support body.

13. The integrated circuit chip of claim 12 wherein the thermal vias are thermally conductive and electrically conductive.

14. The integrated circuit chip of claim 13 wherein the thermal vias comprise copper and/or tungsten.

15. The integrated circuit chip of claim 12 wherein the thermal vias are thermally conductive and electrically resistive.

16. The integrated circuit chip of claim 15 wherein the thermal vias comprise CVD diamond.

17. The integrated circuit chip of claim 12 wherein a first thermal via is thermally conductive and electrically conductive and a second thermal via is thermally conductive and electrically resistive.

18. The integrated circuit chip of claim 17 wherein the first thermal via comprises copper and/or tungsten and the second thermal via comprises CVD diamond.

19. The integrated circuit chip of claim 12 wherein the chip is a three-dimensional (3D) chip comprising:
a first tier comprising a first support body having a plurality of regions free of active devices, at least one thermal via extending through the thickness of the first support body in the regions, and a first heat spreader comprising CVD diamond extending to the side edges along the first support body; and
a second tier comprising a second support body having a plurality of regions free of active devices, with the regions of the second tier vertically aligned with the regions of the first tier, at least one thermal via extending through the thickness of the second support body in the regions, and a second heat spreader comprising CVD diamond extending to the side edges along the second support body, the first heat spreader positioned between the first support body and the second support body.

20. The 3D integrated circuit chip of claim 19 wherein the thermal vias comprise CVD diamond.
